(19) United States
(12) Patent Application Publication
(10) Pub. No.: US 2022/0293547 A1
(43) Pub. Date: Sep. 15, 2022

(54) SEMICONDUCTOR PACKAGING STRUCTURE, METHOD, DEVICE AND ELECTRONIC PRODUCT

(71) Applicant: Yibu Semiconductor Co., Ltd., Shanghai (CN)

(72) Inventor: Weiping LI, Shanghai (CN)

(21) Appl. No.: 17/693,358

(22) Filed: Mar. 12, 2022

(30) Foreign Application Priority Data
Mar. 12, 2021 (CN) 202110269375.8
Mar. 12, 2021 (CN) 202110272185.1

(51) Int. Cl. H01L 23/00; H01L 25/10; H01L 23/13; H01L 23/15

(52) U.S. Cl. CPC H01L 24/24; H01L 25/105; H01L 24/73; H01L 24/19; H01L 24/32; H01L 23/13; H01L 23/15; H01L 2224/73267; H01L 2224/32225; H01L 2224/24137; H01L 23/49822

(57) ABSTRACT

The application provides a semiconductor packaging structure, a semiconductor packaging method, a semiconductor packaging device and an electronic product. The semiconductor packaging structure comprises a substrate, at least one packaged component, a redistribution layer and a passivation layer. The substrate has at least one groove and the at least one packaged component is fixed in the at least one groove in one-to-one correspondence. Each packaged component is separated from a corresponding groove, in which the package component is disposed, by insulating materials. The at least one packaged component has first bonding pads on at least one active surface facing away from the substrate and are flush. The redistribution layer is formed over the at least one active surface. The substrate includes a semiconductor material or insulating material with a thermal expansion coefficient that is the same as or similar to that of a base semiconductor material in the packaged component.

### CROSS REFERENCE TO RELATED APPLICATIONS

The present application claims the benefit of priority under the Paris Convention to Chinese Patent Application No. 202110269375.8, filed Mar. 12, 2021, entitled “Semiconductor Packaging Structure, Method, Device and Electronic Product,” and Chinese Patent Application No. 202110272185.1, filed Mar. 12, 2021, entitled “Semiconductor Packaging Structure, Method, Device and Electronic Product,” each of which is incorporated by reference herein in its entirety. The present application is related to co-pending US Patent Application Attorney Docket No. YB018-05US, entitled “Semiconductor Packaging Structure, Method, Device and Electronic Product,” filed on even date herewith, which is incorporated herein by reference in its entirety.

### FIELD OF THE INVENTION

The present application relates to the technical field of semiconductor manufacturing, in particular to a semiconductor packaging structure, a semiconductor packaging method, a packaged semiconductor device and an electronic product including same.

### BACKGROUND

In a typical semiconductor packaging process, a component (e.g., a die, also referred to as die) needs to be packaged, generally by fixing the component on a substrate, a frame (e.g., lead frame) or an interposer, and then packaging the component in a series of processes such as interconnect formation and molding encapsulation, to obtain a packaged semiconductor device.

### SUMMARY

Certain embodiments are directed to providing a semiconductor packaging structure, a semiconductor packaging method, a packaged semiconductor device and an electronic product including same.

In certain embodiments, a semiconductor package structure comprises a substrate having at least one groove, at least one packaged component fixed in the at least one groove, a redistribution layer and a passivation layer. In some embodiments, the at least one groove is formed in the substrate and corresponds, respectively, to the at least one groove, and each packaged component is fixed in a corresponding one of the at least one groove.

In some embodiments, an active surface of the packaged component faces away from the substrate, the packaged component and the corresponding groove, in which the package component is disposed, are separated by insulating materials. Each packaged component is provided with first bonding pads located on the active surface of the packaged component, and the surfaces of the first bonding pads, which faces away from the substrate, are flush.

In some embodiments, the redistribution layer is positioned on one side of the packaged component opposite to (or facing away from) the substrate, a plurality of second bonding pads are formed on a first surface of the redistribution layer, a plurality of third bonding pads are formed on a second surface, opposite to the first surface, of the redistribution layer, the second bonding pads are in electrical contact with respective ones of the first bonding pads in one-to-one correspondence, and the redistribution layer is further provided with routing wires electrically connected with the second bonding pads and the third bonding pads.

In some embodiments, the passivation layer is positioned on one side of the redistribution layer facing away from the substrate.

In some embodiments, the substrate is formed by a semiconductor material or an insulating material, and the thermal expansion coefficient of the substrate is the same as or similar to that of the semiconductor material in the packaged component.

In some embodiments, a semiconductor packaging method comprises forming at least one groove in a substrate; and fixing at least one packaged component in the at least one groove, such that each packaged component is fixed in a corresponding one of the at least one groove and the active surface of the packaged component faces away from the substrate. In some embodiments, the packaged component is separated from the groove, in which the packaged component is fixed, by one or more insulating materials. Each packaged component is provided with first bonding pads located on the active surface of the packaged component, and the surfaces of the first bonding pads, which faces away from the substrate, are flush.

In some embodiments, the semiconductor packaging method further comprises forming a flat surface where the first bonding pads are exposed.

In some embodiments, semiconductor packaging method further comprises forming a redistribution layer using a wafer manufacturing process. In some embodiments, a plurality of second bonding pads are formed on a first surface of the redistribution layer, and a plurality of third bonding pads are formed on a second surface of the redistribution layer, which is opposite to the first surface. In some embodiments, the second bonding pads are in electrical contact with respective ones of the first bonding pads, and the redistribution layer is also provided with routing wires which are electrically connected with the second bonding pads and the third bonding pads.

In some embodiments, the semiconductor packaging method further comprises forming a passivation layer.

In some embodiments, the substrate is formed of a semiconductor material or an insulating material, and the substrate has the same or similar thermal expansion coefficient as the semiconductor material in the packaged component.

In some embodiments, a semiconductor package structure comprises a substrate, at least one first packaged component, at least one second packaged component, a redistribution layer, and a passivation layer. In some embodiments, formed in the substrate are at least one first groove corresponding, respectively, to the at least one first packaged component, and at least one second groove, corresponding, respectively, to the at least one second packaged component. In some embodiments, the at least one first packaged component is fixed in the at least one first groove in a one-to-one corresponding manner, the second packaged components are fixed in the at least one second groove in a one-to-one corresponding manner, the first packaged component is in a bare chip state, and the second packaged component is in a packaged state and is provided with an exposed second electrode structures.

In some embodiments, the active surface of the at least one first packaged component faces away from the substrate, each first packaged component is separated from the corresponding first groove where the first packaged component is located by one or more insulating materials, each second packaged component is separated from a corresponding second groove where the second packaged component is located by one or more insulating materials, the at least one first packaged component is provided with first bonding pads on at least one active surface of the first packaged component, surfaces of the first bonding pads facing away from the substrate and surfaces of the second electrode structures facing away from the substrate are flush.

In some embodiments, the redistribution layer is formed on one side of the packaged components facing away from the substrate and includes a plurality of second pads on a first surface of the redistribution layer and a plurality of third pads on a second surface, opposite to the first surface, of the redistribution layer. The first bonding pads are respectively and electrically connected to a first subset of the second pads, the second electrode structures are respectively and electrically connected with a second subset of the second pads, and the redistribution layer is further provided with routing wires for electrically connecting the second pads and the third pads and routing wires for electrically connecting certain second pads and certain second electrode structures.

In some embodiments, the passivation layer is positioned on one side of the redistribution layer facing away from the substrate.

In some embodiments, the substrate is formed of a semiconductor material or an insulating material that has the same or similar thermal expansion coefficient as that of a base semiconductor material in the packaged component.

In some embodiments, a semiconductor packaging method comprises forming at least one first groove and at least one second groove in a substrate, fixing at least one first packaged component in the at least one first groove in a one-to-one correspondence manner, and fixing at least one second packaged component in the at least one second groove in a one-to-one correspondence manner. In some embodiments, the at least one first packaged component is in a bare chip state, and the at least one second packaged component is in a packaged state and has exposed second electrode structures. In some embodiments, the active surface of the at least one first packaged component faces away from the substrate, each first packaged component is separated from the corresponding first groove where the first packaged component is located by one or more insulating materials, each second packaged component is separated from a corresponding second groove where the second packaged component is located by one or more insulating materials, the at least one first packaged component is provided with first bonding pads on at least one active surface of the first packaged component, surfaces of the first bonding pads facing away from the substrate and surfaces of the second electrode structures facing away from the substrate are flush.

In some embodiments, the semiconductor packaging method further comprises forming a planar surface exposing the first bonding pads and the second electrode structure;

In some embodiments, the semiconductor packaging method further comprises forming a redistribution layer, including a plurality of second pads on a first surface of the redistribution layer and a plurality of third pads on a second surface, opposite to the first surface, of the redistribution layer. The first bonding pads are respectively and electrically connected to a first subset of the second pads, the second electrode structures are respectively and electrically connected with a second subset of the second pads, and the redistribution layer is further provided with routing wires for electrically connecting the second pads and the third pads and routing wires for electrically connecting certain second pads and certain second electrode structures

In some embodiments, the semiconductor packaging method further comprises forming a passivation layer.

In some embodiments, the substrate is formed of a semiconductor material or an insulating material, and the substrate has the same or similar thermal expansion coefficient as that of the semiconductor material in the packaged component.

In some embodiments, a semiconductor device comprising the foregoing semiconductor packaging structure is provided.

In some embodiments, an electronic product comprising the foregoing semiconductor device is provided.

The embodiments provide several benefits, as compared with conventional packaging technologies, as discussed in the following.

Because the thermal expansion coefficients of the semiconductor material in the packaged component and the substrate are equal or close (for example, the two are made of a same semiconductor material), after the packaging is completed, the warpage of the semiconductor packaging structure generated due to changes in temperature is relatively small, resulting in improved yield and electrical and mechanical reliability of the semiconductor device. Also, in some embodiments, the semiconductor substrate provides better heat dissipation than the molding material of conventional packaging forms.

### BRIEF DESCRIPTION OF THE DRAWINGS

FIGS. 1a and 1b are schematic structural diagrams of two semiconductor package structures according to some embodiments.

FIG. 2 is a schematic flow chart of a semiconductor packaging method according to some embodiments.

FIGS. 3a to 3g are schematic product states of the semiconductor package structure shown in FIG. 1a at different stages of packaging in accordance with some embodiments.

FIGS. 4a to 4g are schematic product states of the semiconductor package structure shown in FIG. 1B at different stages of packaging in accordance with some embodiments.

FIGS. 5a and 5b are schematic structural diagrams of two semiconductor package structures, respectively, according to some embodiments.

FIG. 6 is a flow chart illustrating a semiconductor packaging method according to some embodiments.

FIGS. 7a to 7f are schematic product states of the semiconductor package structure shown in FIG. 5a at different stages of packaging in accordance with some embodiments.

FIGS. 8a to 8f are schematic product states of the semiconductor package structure shown in FIG. 5b at different stages of packaging in accordance with some embodiments.

In the drawings, 1 denotes a substrate; 10 denotes a groove; 111 or 112 denotes an insulating material; 21 or 22 denotes an packaged component; 211 or 221, denotes a first pad; 3 denotes a redistribution layer; 31 denotes a second pad; 32 denotes a third pad; 33 denotes routing; 4 denotes a passivation layer; 5 denotes an electrode structure; 21a denotes a second packaged component; 22a or 23a denotes a first packaged component; 211a denotes a second electrode structure; 221a or 231a denotes a first pad.

### DETAILED DESCRIPTION OF THE EMBODIMENTS

In this application, it will be understood that terms such as “including” or “having,” or the like, are intended to indicate the presence of the disclosed features, numbers, steps, acts, components, parts, or combinations thereof, but do not preclude the presence or addition of one or more other features, numbers, steps, acts, components, parts, or combinations thereof

It should be noted that the embodiments and features of the embodiments described herein may be combined with each other without conflict. Some embodiments will be described in detail below with reference to examples shown in the attached drawings.

Some embodiments provide a semiconductor package structure, comprising: a substrate having at least one groove, at least one packaged component fixed in the at least one groove, a redistribution layer, and a passivation layer. The at least one groove is formed in the substrate and corresponds, respectively, to the at least one groove, and each packaged component is fixed in a corresponding one of the at least one groove. An active surface of the packaged component faces away from the substrate, and the packaged component and the corresponding groove, in which the package component is disposed, are separated by insulating materials. Each packaged component is provided with first bonding pads located on the active surface of the packaged component, and the surfaces of the first bonding pads, which faces away from the substrate, are flush. The redistribution layer is positioned on one side of the packaged component opposite to (or facing away from) the substrate, a plurality of second bonding pads are formed on a first surface of the redistribution layer, a plurality of third bonding pads are formed on a second surface, opposite to the first surface, of the redistribution layer, and the second bonding pads are in electrical contact with respective ones of the first bonding pads in one-to-one correspondence. The passivation layer is positioned on one side of the redistribution layer facing away from the substrate. The substrate is formed by a semiconductor material or an insulating material.

Because the thermal expansion coefficients of the semiconductor material in the packaged component and the substrate are same or similar, after the packaging is completed, the warpage of the semiconductor packaging structure resulted from changes in temperature is relatively small, the yield and electrical and mechanical reliability of the semiconductor device are improved, and at the same time, the semiconductor substrate dissipates heat better than the conventional molding material used in conventional packaging techniques.

For example, a semiconductor material in the substrate is the same as a base semiconductor material in the packaged component.

In some embodiments, each packaged component is placed in a corresponding groove or recess formed in the substrate, and the top (e.g., active) side of the packaged component is covered by a redistribution layer. The substrate and the base material in the packaged component are the same semiconductor material.

By referring to two elements as having or being of “the same semiconductor material” in this application, it is to indicate that they include semiconductor materials of the same chemical composition, e.g., both are formed of silicon material, or both are formed of gallium arsenide material, etc. However, these semiconductor materials are not limited to having the same uniformity, purity, density, crystalline state, or the like.

As another example, the semiconductor material in the packaged component is silicon or gallium arsenide, and the material of the substrate is engineered Pyrex. Their coefficients of thermal expansion are of the same order of magnitude.

In the present application, the close thermal expansion coefficients of the two materials mean that the absolute value of the ratio of the difference between the two to the smaller of the two is less than 9.

In some embodiments, the packaged component is in the state of a bare die.

In some embodiments, a single semiconductor package structure includes one packaged component. The role of the redistribution layer is to lead out the first bonding pads on the packaged component.

In some embodiments, multiple packaged components are included in a single semiconductor package structure, and the wires in the redistribution layer may function as signal interconnections between the first bonding pads of the plurality of packaged components.

In some embodiments, the at least one packaged component includes multiple packaged components equal in thickness, and the depth of each groove is equal.

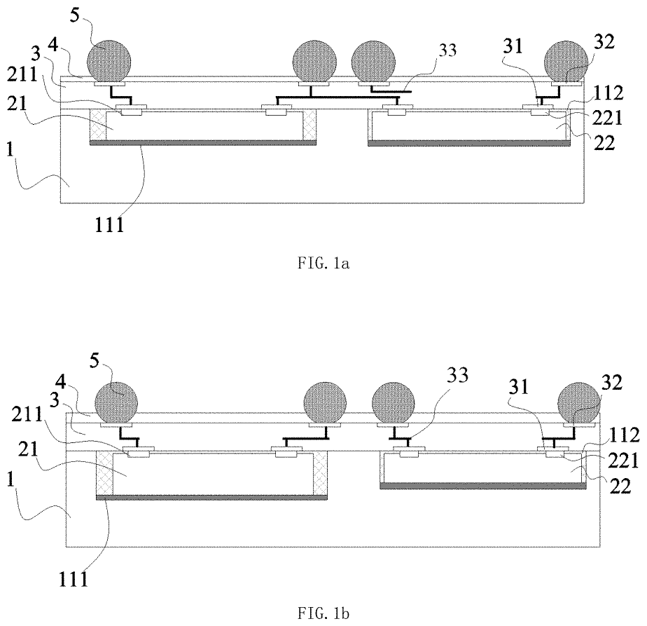

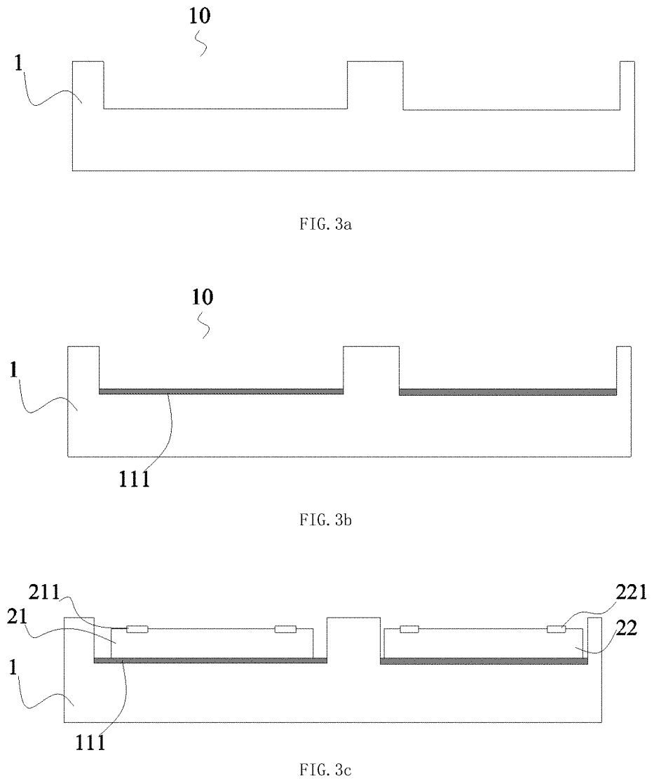

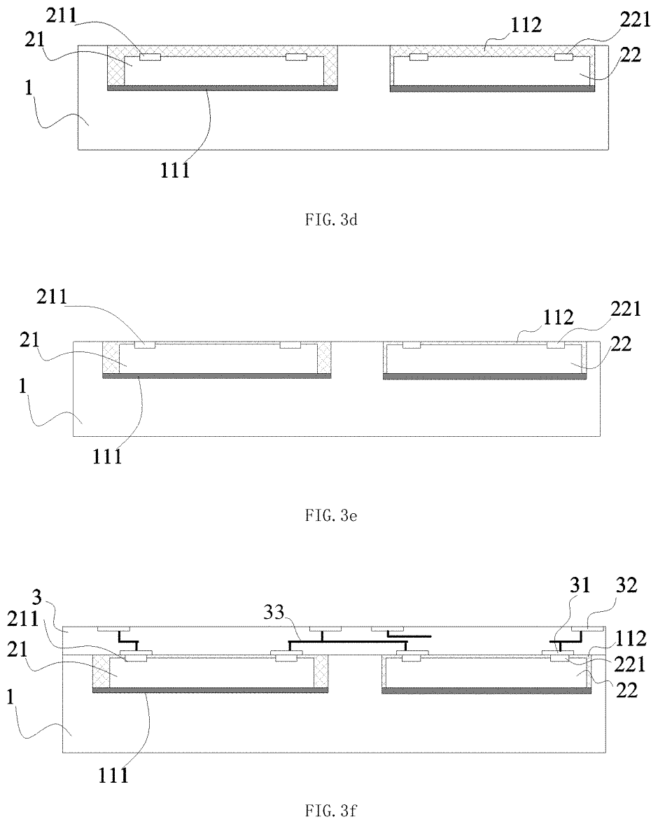

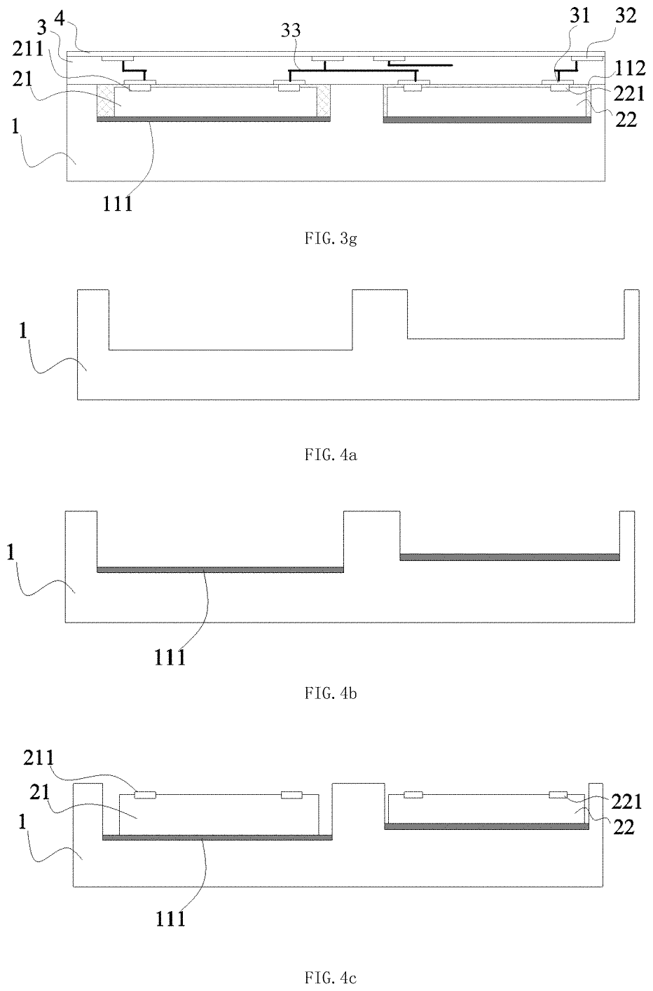

Referring to FIGS. 1a and 3a, the thickness of the packaged component 21 and the packaged component 22 are equal, and the depth of the recess 10 is equal.

In some embodiments, the packaged components 21 and 22 may be the same type of packaged component or different types of packaged components. Since the thickness of packaged component 21 and packaged component 22 are equal, each recess 10 can be formed using the same grooving (e.g., etching) process.

If the original thicknesses of the packaged components are not uniform, the thicknesses of the packaged components can be made equal through a thinning process.

In some embodiments, even if the original thicknesses of these packaged components 21, 22 are equal, their thicknesses can be reduced and equal by a thinning process. In this manner, the groove depth of the recess 10 formed in the substrate 1 can be reduced.

In some embodiments, the at least one packaged component includes at least two packaged components, and the thicknesses of at least two packaged components are not equal, wherein the depths of at least two grooves are different, so that the upper surfaces of the first bonding pads of the packaged components are flush.

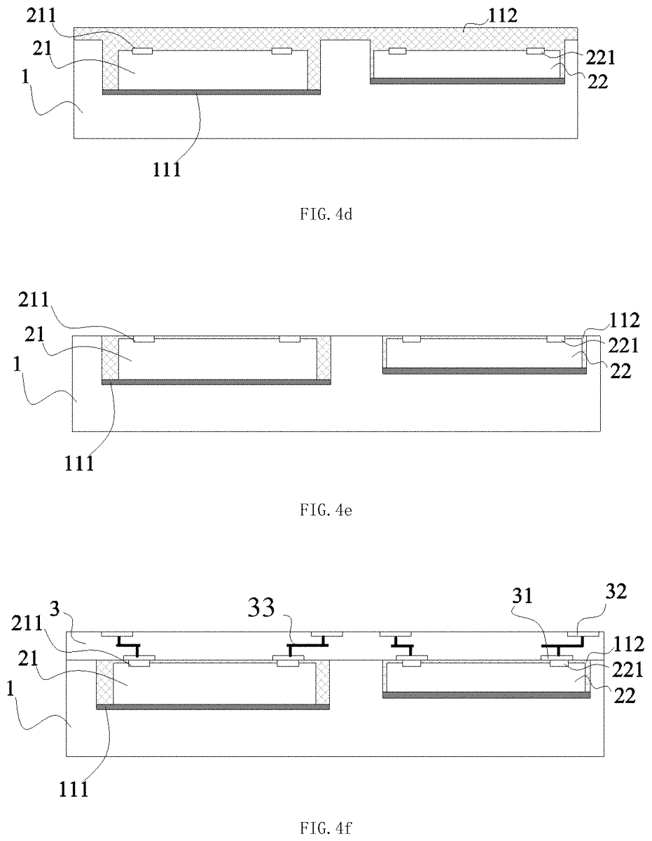

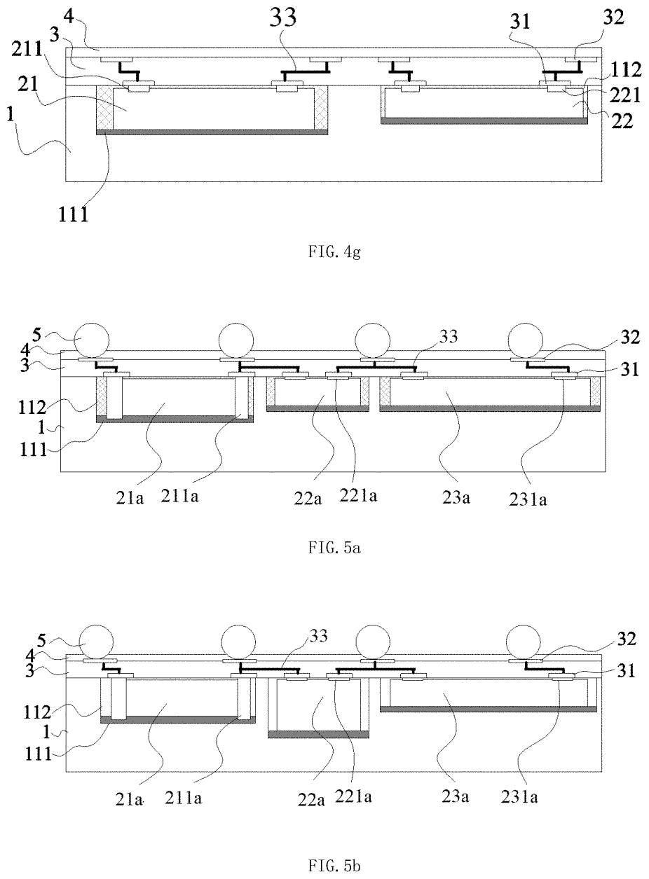

Referring to FIG. 1B and 4a, the thickness of the packaged component 21 and the packaged component 22 are not equal, nor are they equal in the depth of the recess 10. The packaged component 21 is thicker and, correspondingly, is located at a greater depth in the recess 10.

The grooves 10 of different depths can be formed by controlling the etching process used to form the grooves, such as step etching or double etching.

In some embodiments, after the passivation layer covers the third bonding pad above the redistribution layer, the semiconductor packaging structure can be used as a product for independent sale.

In some embodiments, referring to FIGS. 1a and 1b, the semiconductor package structure further includes electrode structures 5 on a side of the passivation layer 4 facing away from the substrate 1. Via holes (not shown) can be opened from a side of the passivation layer 4 opposite to the side of the passivation layer facing the third pad 32. The electrode structures 5 correspond, respectively, to the third pads 32, and are respectively and electrically connected to the corresponding third pads 32 through respective via holes.

Specifically, an electrode structure 5 includes, for example, an Under Bump Metal (UBM) covering a third pad, and a solder ball located above the under bump metal. Or, the electrode structure may also be a Pad formed over the third Pad.

In some embodiments, the packaged component is separated from the groove bottom of the groove by an insulating adhesive layer. For example, the packaged component is fixed by the insulating adhesive layer, which also serves as insulation between the packaged component and the groove bottom of the groove.

In some embodiments, the packaged component is separated from the sides or side surfaces of the recess by a cured resin material (e.g., epoxy) or an inorganic insulating material. A resin material may be filled and cured into the gap between the packaged component and the side surfaces of the recess, or an inorganic insulating material (e.g., silicon dioxide) may be deposited into the gap.

In some embodiments, the conductors in the redistribution layer are separated from one another by the polymer. The polymer in the redistribution layer can be, for example, Polyimide (PI) or Polymethylene Benzobisoxazole (PBO). For example, the conductors in the redistribution layer are separated from each other by a molding compound.

The redistribution layer comprises at least one layer of metal wires and through holes for connecting different layers of metal wires (if multiple layers of metal wires are provided), the metal wires and the second bonding pads, and/or the metal wires and the third bonding pads. The routings in the redistribution layer can realize the interconnection of the second bonding pads and the third bonding pads, the interconnection among the second bonding pads, and the interconnection among the third bonding pads.

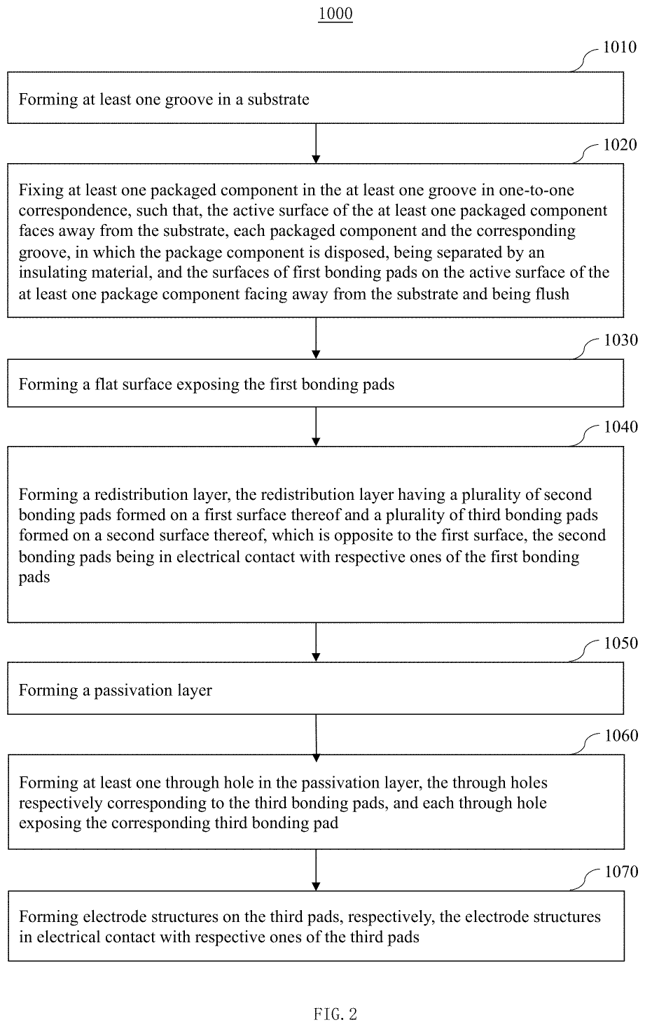

Referring to FIG. 2, some embodiments further provides a semiconductor packaging method 1000. The packaging method 1000 can be used to manufacture the semiconductor packaging structure in accordance with some embodiments. The packaging method 1000 includes steps 1010-1050, as described in the following.

Step 1010—forming at least one groove in a substrate. In some embodiments, the substrate is made of semiconductor material or insulating material, and the substrate material has the same or similar thermal expansion coefficient as the base material in a to-be-packaged or packaged component.

Step 1020—fixing at least one packaged component in the at least one groove in a one-to-one correspondence manner. In some embodiments, the active surface of the at least one packaged component faces away from the substrate, and each packaged component and the corresponding groove, in which the package component is disposed, are separated by one or more insulating materials. Each packaged component is provided with first bonding pads located on the active surface of the packaged component, and the surfaces of the first bonding pads, which faces away from the substrate, is flush;

Step 1030—forming a flat surface exposing the first bonding pads. In some embodiments, a surface treatment process such as chemical cleaning, polishing, etc. is performed to obtain a flat surface exposing the first bonding pads.

Step 1040—forming a redistribution layer. In some embodiments, a plurality of second bonding pads are formed on a first surface of the redistribution layer, and a plurality of third bonding pads are formed on a second surface of the redistribution layer, which is opposite to the first surface. In some embodiments, the second bonding pads are in electrical contact with respective ones of the first bonding pads, and the redistribution layer is also provided with routing wires which are electrically connected with the second bonding pads and the third bonding pads.

Step 1050—forming a passivation layer. In some embodiments, the passivation layer is formed over the redistribution layer.

In some embodiments, the substrate is formed of a semiconductor material or an insulating material, and the substrate has the same or similar thermal expansion coefficient as the semiconductor material in the packaged component.

In some embodiments, the semiconductor material in the substrate is the same as the base semiconductor material in the packaged component.

In some embodiments, the semiconductor material in the packaged component is silicon or gallium arsenide, and the material of the substrate is engineered Pyrex.

In some embodiments, the coefficients of thermal expansion of the insulating material in the packaged component and the insulating material in the redistribution layer are the same or similar.

For example, the insulating material in the redistribution layer and the insulating material in the packaged component both comprise silicon dioxide or both comprise polysilicon.

Because the thermal expansion coefficients of the semiconductor material in the packaged component and the substrate are the same or similar, after the packaging is completed, the warpage of the semiconductor packaging structure resulted from changes in temperature is relatively small, and the yield and electrical and mechanical reliability of the semiconductor device including the semiconductor packaging structure are improved.

The thermal conductivity of silicon and engineering Pyrex is also higher than that of the conventional molding compound, and the heat dissipation of the semiconductor package structure is also higher.

In some embodiments, the packaging method 1000 further comprises steps 1060 and 1070, as described in the following.

Step 1060—forming at least one through hole on the passivation layer. In some embodiments, the through holes respectively correspond to the third bonding pads, and the through holes expose the corresponding third bonding pads.

Step 1070—forming electrode structures on the third pads, respectively, the electrode structures in electrical contact with respective ones of the third pads.

In some embodiments, the at least one packaged component includes at least two packaged components corresponding respectively to at least two grooves of the same depth, and the packaging method 1000 further comprises: thinning at least one of the packaged components so that the packaged components have equal thickness.

In some embodiments, the at least one packaged component includes at least two packaged components of unequal thicknesses, and the depths of at least two grooves are not equal when the grooves are formed in the substrate, so that the upper surfaces of the first bonding pads of different packaged components are flush.

In some embodiments, fixing the at least one packaged component in the at least one recess in one-to-one correspondence includes: forming an insulating adhesive layer at the bottom of a groove; affixing a packaged component on the insulating adhesive, reserving a gap between the packaged component and each side surface of the groove; and filling the gap between the packaged component and each side surface of the corresponding groove with an insulating material.

In some embodiments, filling the gap between the packaged component and each side surface of the corresponding groove with an insulating material includes: filling the gap b between the packaged component and each side surface of the corresponding groove with a resin material and curing the resin material; or depositing an inorganic oxide insulating material into the gap between the packaged component and each side surface of the corresponding groove.

In some embodiments, forming a flat (or planar surface) exposing the first bonding pads includes removing the insulating material and the substrate material above the first bonding pads by a grinding process, followed by a surface treatment.

In some embodiments, the substrate can have sufficient area allowing the formation of a number of grooves. The method 1000 further comprises obtaining a plurality of semiconductor packaging structures using a dicing process. Each semiconductor packaging structure at least comprises: a packaged component, a recess in which the packaged component is located, a redistribution layer electrically connected to the packaged component, and a passivation layer over the redistribution layer.

In some embodiments, the packaged component is bare die or in the state of a bare die before being fixed in the corresponding groove.

In some embodiments, the insulating material in the redistribution layer comprises a polymer or a molding compound.

Referring to FIGS. 3a to 3g and FIG. 1a, a specific implementation process of the packaging method 1000 to form a semiconductor device is described in accordance with some embodiments.

Referring to FIG. 3a, in step 1010, a plurality of grooves 10 are formed on a substrate 1 by an etching process, and the plurality of grooves 10 have the same depth.

Referring to FIG. 3b, an insulating adhesive layer 111 is formed at the bottom of the groove 10.

Referring to FIG. 3c, in step 1020, the packaged component 21 and the packaged component 22 are respectively placed in respective grooves 10 and adhered to the insulating adhesive 111, wherein the first bonding pads 211 of the packaged component 21 and the first bonding pads 221 of the packaged component 22 face upward (away from the substrate), and the thicknesses of the packaged component 21 and the packaged component 22 are equal. Each of packaged components 21 and 22 are spaced from the side walls of the recess 10 in which they are located.

Referring to FIG. 3d, the recess 10 is filled with the insulating material 112. For example, a liquid epoxy resin is dropped into the gap between the groove 10 and the packaged components 21 and 22, and the epoxy resin is cured by heating. Or an inorganic insulating material (for example silicon dioxide) is deposited into the gap between the recess 10 and the packaged components 21, 22.

Referring to FIG. 3e, in step 1030, portions of the insulating material 112 higher than the first bonding pads 211 and 221 and portions of the substrate material higher than the first bonding pads 211 and 221 are removed by grinding, and a surface treatment process such as chemical cleaning, polishing, etc. is performed to obtain a flat or planar surface exposing the first bonding pads 211 and 221.

Referring to FIG. 3f, in step 1040, a redistribution layer 3 is formed on the planar surface, the second electrodes 31 of the redistribution layer 3 is electrically contacted with the first bonding pads 211, 221, respectively, and the third electrodes 32 of the redistribution layer 3 is interconnected with the second electrodes 31.

Specifically, for example, a polyimide film is formed, and a patterning process (e.g., photoresist coating, exposure, development, etching) is performed to form via holes exposing the first bonding pads 211 and 221 in the polyimide film. Afterwards, the method comprises depositing a metal film, forming a wire 33 connected to each first bonding pad 211 and 221 through a patterning process, and forming a second bonding pad 31 by using a metal material in a lower layer via hole. Afterwards, a layer of polyimide film and a layer of wiring 33 are formed again, a polyimide film is formed, a partial region of the lower trace 33 is exposed through a patterning process, and finally, a metal film is deposited, and a third pad 32 connected to the lower trace 33 is formed through the patterning process.

The redistribution layer may include a plurality of layers of traces 33.

In some embodiments, the patterning process may be used to form the second pads 31 first, followed by forming the polyimide film, forming the via hole in the polyimide film to expose the second pad 31, and then forming the pattern of the first layer traces 33.

The redistribution layer can also be prepared by those skilled in the art using conventional technologies

Referring to FIG. 3g, in step 1050, a passivation layer 4 is formed on the redistribution layer 3. The passivation layer 4 may be made of silicon nitride (sin), polyimide (polyimide), or the like. The passivation layer 4 serves to protect the elements therebelow.

Referring to FIG. 1a, in step 1060, vias can be etched in the passivation layer 4 to expose the respective third electrodes 32, and, in step 1070, the electrode structures 5 are formed on the third electrodes 32. An electrode structure 5 includes, for example, Under Bump Metal (UBM) on a third electrode 32 and solder balls on the under-bump metal. The electrode structure 5 may also be in the form of a pad.

Referring to FIGS. 4a to 4g and FIG. 1B, the packaging method 1000 for manufacturing a semiconductor device can be implemented as follows in accordance with some embodiments.

Referring to FIG. 4a, in step 1010, a plurality of grooves 10 are formed on a substrate 1 by controlling a grooving process (e.g., step etching or secondary etching), wherein the plurality of grooves 10 have different depths.

Referring to FIG. 4b, an insulating adhesive layer 111 is formed at the bottom of each groove 10.

Referring to FIG. 4c, in step 1020, the packaged component 21 and the packaged component 22 are respectively placed in respective grooves 10 and adhered to the insulating adhesive 111. In some embodiments, the thicknesses of the packaged component 21 and the packaged component 22 are not equal, but the first bonding pads 211 of the packaged component 21 and the first bonding pads 221 of the packaged component 22 face upward and are flush.

Referring to FIG. 4d, an insulating material 112 is filled and cured into the recess 10. For example, a liquid epoxy resin is dropped into the gap between sidewalls of the groove 10 and the packaged components 21 and 22, and the epoxy resin is cured by heating.

Referring to FIG. 4e, in step 1030, the insulating material higher than the first bonding pads 211 and 221 and the substrate material higher than the first bonding pads 211 and 221 are removed by grinding, and a surface treatment process such as chemical cleaning, polishing, etc. is performed to obtain a flat surface exposing the first bonding pads 211 and 221.

Referring to FIG. 4f, in step 1040, a redistribution layer 3 is formed on the planar surface, the second electrodes 31 of the redistribution layer 3 are electrically contacted with the first bonding pads 211, 221, respectively, and the third electrodes 32 of the redistribution layer 3 is interconnected with the second electrodes 31.

Specifically, for example, a polyimide film is formed, and then a patterning process (e.g., photoresist coating, exposure, development, etching) is performed to form via holes exposing the first bonding pads 211 and 221 in the polyimide film. Afterwards, a process including the following is performed: depositing a metal film, forming a wire 33 connected to each first bonding pad 211 and 221 through a patterning process, forming a second bonding pad 31 by using a metal material in a lower layer via hole. Thereafter, a polyimide film is formed, a partial region of the lower traces 33 is exposed through a patterning process, and finally, a metal film is deposited, and third pads 32 connected to the lower traces 33 is formed through the patterning process.

The redistribution layer may include a plurality of layers of traces 33.

Referring to FIG. 4g, in step 1050, a passivation layer 4 is formed on the redistribution layer 3. The passivation layer 4 may be made of silicon nitride (SiN), polyimide, or the like. The passivation layer 4 serves to protect the elements therebelow.

Referring to FIG. 4a, in step 1060, vias are etched in the passivation layer 4 to expose the respective third electrodes 32, and, in step 1070, the electrode structures 5 are formed on the third electrodes 32. An electrode structure 5 includes, for example, Under Bump Metal (UBM) over a third electrode 32 and a solder ball over the under bump metal. The electrode structure 5 may also be a bonding pad.

Some embodiments provides a semiconductor package structure, which comprises a substrate, at least one first packaged component, at least one second packaged component, a redistribution layer, and a passivation layer. In some embodiments, at least one first groove and at least one second groove are formed in the substrate, the at least one first packaged component is fixed in the at least one first groove in one-to-one correspondence, the at least one second packaged component is fixed in the at least one second groove in one-to-one correspondence, each first packaged component is separated from a corresponding first groove, in which the first package component is disposed, by insulating materials, and each second packaged component is separated from a corresponding second groove, in which the second package component is disposed, by insulating materials. In some embodiments, the at least one first packaged component is in a bare chip state and has at least one active surface facing away from the substrate and first bonding pads on the at least one active surface, the at least one second packaged component is in a packaged state and is provided with exposed second electrode structures, and surfaces of the first bonding pads facing away from the substrate and surfaces of the second electrode structures facing away from the substrate are flush.

In some embodiments, the redistribution layer is formed on one side of the at least one packaged component facing away from the substrate, the redistribution layer has a first surface formed with a plurality of second bonding pads and a second surface opposite to the first surface and formed with a plurality of third bonding pads, a first subset of the second bonding pads are in electrical contact with respective ones of the first bonding pads, a second subset of the second bonding pads are in electrical contact with respective ones of the second electrode structures, and the redistribution layer further includes routing wires to provide electrical interconnection between the second bonding pads and the third pads and routing wires to provide electrical interconnection between the second bonding pads and the second electrode structures.

In some embodiments, the passivation layer is positioned on one side of the redistribution layer facing away from the substrate.

In some embodiments, the substrate includes a semiconductor material or an insulating material having a thermal expansion coefficient that is the same as or similar to that of a base semiconductor material in the at least one first packaged component.

For example, the base semiconductor material in the substrate is the same as the semiconductor material in the packaged component.

As another example, the base semiconductor material in the packaged component is silicon or gallium arsenide, and the material of the substrate is engineering Pyrex.

In some embodiments, the first packaged component is disposed in a first recess formed in the substrate, the second packaged component is disposed in a second recess formed in the substrate, and the first packaged component and the second packaged component are covered by the redistribution layer. The base material in the substrate is the same as the base material in the first packaged component.

The first packaged component is in a bare chip state, and the second packaged component is an element which is packaged. The semiconductor packaging structure realizes primary packaging of a first packaged component and secondary packaging of a second packaged component, and realizes interconnection between the first packaged component and the second packaged component.

The second packaged component is packaged in the form of a chip package, a ceramic package, or the like. The second packaged component may be, for example, a chip resistor, a chip multilayer ceramic capacitor, or the like, or may be another component already in a packaged state.

The shape and position of each second electrode structure of the same second packaged component are not limited in the present application, as long as the second electrode structures have flush surfaces, so as to realize coplanarity with the surfaces of the first bonding pads of the first packaged component.

By referring to two elements as having “the same semiconductor material” in this application, it is to indicate that they include semiconductor materials of the same chemical composition, e.g., both are formed of silicon material, or both are formed of gallium arsenide material, etc. However, these semiconductor materials are not limited to having the same uniformity, purity, density, crystalline state, or the like.

Because the thermal expansion coefficients of the first packaged component and the substrate are the same or similar, after the packaging is finished, the warpage of the semiconductor device caused by temperature change is relatively small and the yield of the semiconductor packaging structure and the electrical and mechanical reliability are improved. Also, in some embodiments, the semiconductor substrate dissipates heat better than the molding material of conventional packaging forms.

Further, the semiconductor packaging structure realizes secondary packaging of the second packaged component and interconnection between the first packaged component and the second packaged component, resulting in higher level of integration.

In some embodiments, the at least one first packaged component includes multiple first packaged components equal in thickness, and the at least one first groove includes multiple first grooves equal in depth.

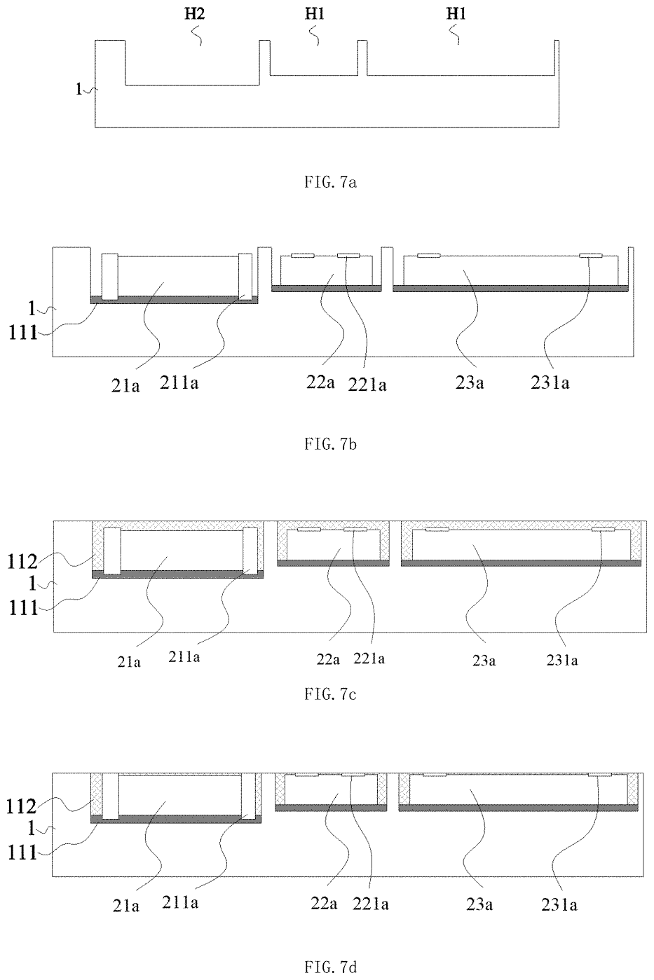

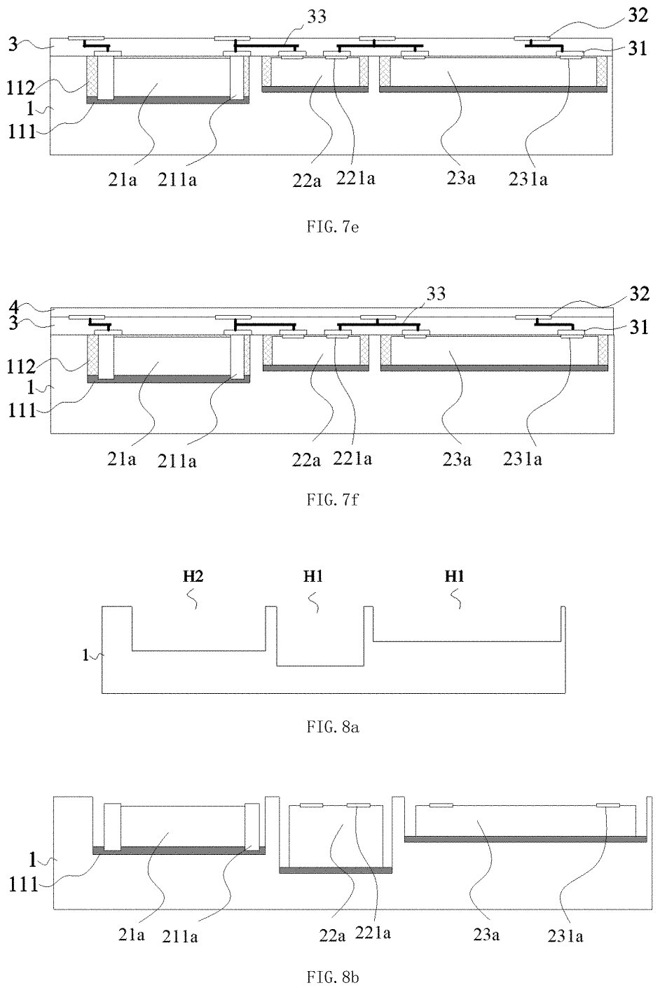

Referring to FIGS. 5a and 7a, the thicknesses of the first packaged components 22a and 23a are equal, and the depths of the first grooves H1 are equal.

In some embodiments, the first packaged component 22a and the first packaged component 23a may be packaged components of the same type or packaged components of different types. Since the thicknesses of the first packaged component 22a and the first packaged component 23a are equal, each first groove 10 can be formed using the same grooving (e.g., etching) process.

If the initial thicknesses of these first packaged components are not uniform, they may be made equal by a thinning process.

In some embodiments, even if the initial thicknesses of these first packaged components 22a, 23a are equal, their thicknesses can be reduced and made equal by a thinning process. In this manner, the groove depth of the recess 10 formed in the substrate 1 can be reduced.

Since the second packaged component 21a is in an encapsulated state, its external dimensions are relatively fixed. The depth of the second recess is largely predetermined and the adjustable margin is relatively small. It is preferred that a relatively thin second packaged component be added to the semiconductor package structure.

In some embodiments, the at least one first packaged component includes at least two first packaged components, and the thicknesses of at least two first packaged components are not equal, wherein the depths of at least two first grooves are different, so that the upper surfaces of the first bonding pads of the first packaged components are flush.

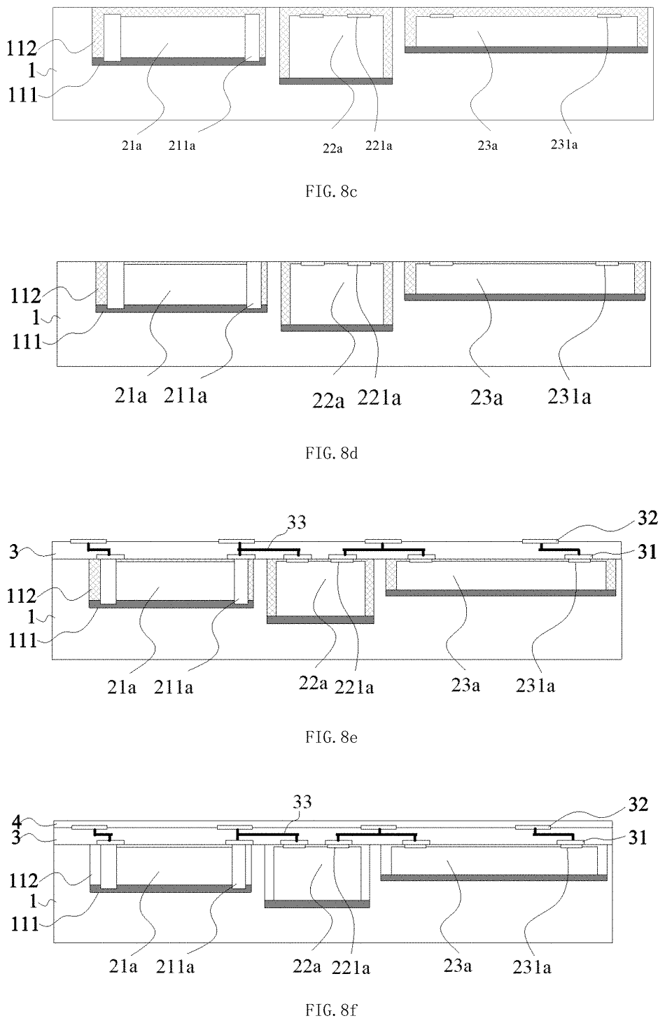

Referring to FIGS. 5b and 8a, the thicknesses of the first packaged component 22a and the first packaged component 23a are not equal, and the depths of the first grooves H1 are not equal. The first packaged component 22a is thicker and, correspondingly, is located at a greater depth in the first recess H1.

The first groove H1 and the second groove H2 may be formed to different depths by controlling a grooving process such as step etching or secondary etching.

In some embodiments, after the passivation layer covers the third bonding pads above the redistribution layer, the semiconductor packaging structure can be used as a product for independent sale.

In some embodiments, referring to FIGS. 5a and 5b, the semiconductor package structure further includes electrode structures 5 on a side of the passivation layer 4 facing away from the substrate 1. Via holes (not shown) can be opened from a side of the passivation layer 4 opposite to the side of the passivation layer facing the third pad 32. The electrode structures 5 correspond, respectively, to the third pads 32, and are respectively and electrically connected to the corresponding third pads 32 through respective via holes.

Specifically, a first electrode structure 5 includes, for example, an Under Bump Metal (UBM) covering a third pad, and a solder ball located above the under bump metal. The first electrode structure may also be a Pad formed over the third Pad.

In some embodiments, each first packaged component is separated from the groove bottom of a corresponding first groove by an insulating adhesive layer, and each second packaged component is separated from the groove bottom of a corresponding second groove by an insulating adhesive layer. For example, the first or second packaged component is fixed by the insulating adhesive layer, which also serves as insulation between the first or second packaged component and the groove bottom of the first or second groove.

In some embodiments, the first packaged component is separated from the side of the first recess by a cured resin material (e.g., epoxy) or an inorganic insulating material; the second packaged component is separated from the side of the second recess by a cured resin material (e.g., epoxy) or an inorganic insulating material. The gaps between the packaged components and the recesses in which they are located may be filled and cured with a resin material or an inorganic insulating material (e.g., silicon dioxide) may be deposited into the gaps.

In some embodiments, conductors in the redistribution layer are separated from one another by a polymer. The polymer in the redistribution layer can be, for example, Polyimide (PI) or Polymethylene Benzobisoxazole (PBO). Also, for example, the conductors in the distribution layer may be separated from each other by a molding compound.

The redistribution layer comprises at least one layer of metal traces and through holes for connecting different layers of metal traces (if multiple layers of metal traces are included), the metal traces and the second bonding pads, and/or the metal traces and the third bonding pads. The routings in the redistribution layer can realize the interconnection of the second pads and the third pads, the interconnection of the second pads and the second electrode structures, and the interconnection of certain second pads and other second pads.

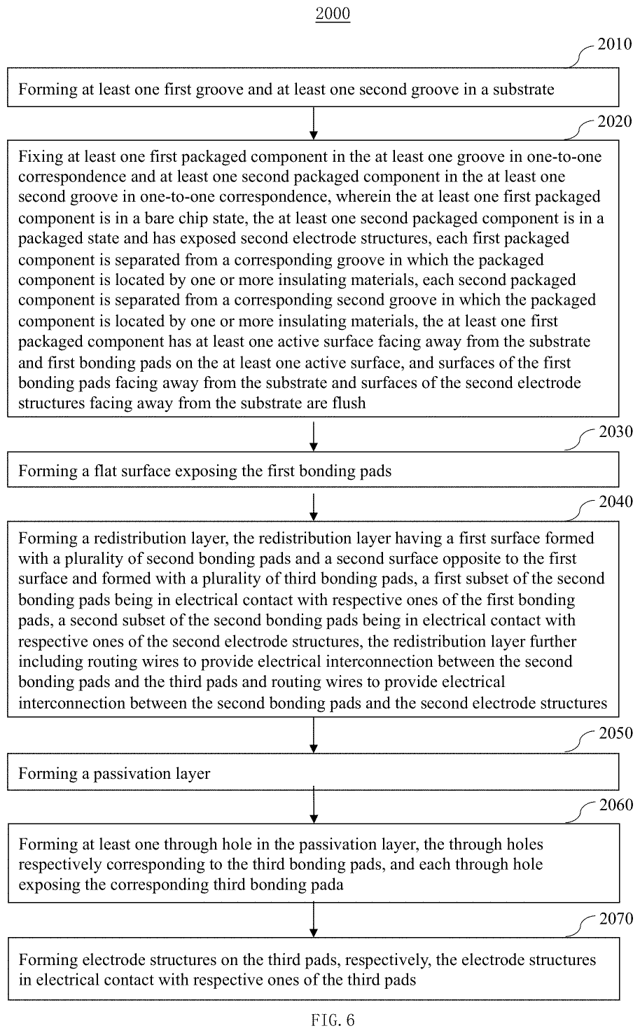

Referring to FIG. 6, some embodiments also provide a semiconductor packaging method 2000. The packaging method 2000 can be used to manufacture the semiconductor packaging structure provided by some embodiments. The manufacturing method 2000 includes steps 2010-2050.

Step 2010—forming at least one first groove and at least one second groove in a substrate.

Step 2020—fixing at least one first packaged component in the at least one groove in one-to-one correspondence and at least one second packaged component in the at least one second groove in one-to-one correspondence. In some embodiments, the at least one first packaged component is in a bare chip state, the at least one second packaged component is in a packaged state and has exposed second electrode structures, each first packaged component is separated from a corresponding groove in which the packaged component is located by one or more insulating materials, each second packaged component is separated from a corresponding second groove in which the packaged component is located by one or more insulating materials, the at least one first packaged component has at least one active surface facing away from the substrate and first bonding pads on the at least one active surface, and surfaces of the first bonding pads facing away from the substrate and surfaces of the second electrode structures facing away from the substrate are flush.

Step 2030—forming a planar surface exposing the first bonding pads and the second electrode structures.

Step 2040—forming a redistribution layer, the redistribution layer having a first surface formed with a plurality of second bonding pads and a second surface opposite to the first surface and formed with a plurality of third bonding pads, a first subset of the second bonding pads being in electrical contact with respective ones of the first bonding pads, a second subset of the second bonding pads being in electrical contact with respective ones of the second electrode structures, the redistribution layer further including routing wires to provide electrical interconnection between the second bonding pads and the third pads and routing wires to provide electrical interconnection between the second bonding pads and the second electrode structures.

Step 2050—forming a passivation layer.

In some embodiments, the substrate includes a semiconductor material or an insulating material, and a thermal expansion coefficient of the substrate is the same as or similar to that of a base semiconductor material in the at least one first packaged component.

For example, the semiconductor material in the substrate is the same as the semiconductor material in the packaged component.

As another example, the semiconductor material in the packaged component is silicon or gallium arsenide, and the material of the substrate is engineering Pyrex.

Because the thermal expansion coefficients of the semiconductor material and the substrate in the first packaged component is the same or similar, the warpage of the semiconductor packaging structure caused by temperature change is relatively small after the packaging is finished, and the yield of the semiconductor packaging structure and the electrical and mechanical reliability are improved.

Also, the thermal conductivity of semiconductor materials and engineering Pyrex is higher than that of conventional molding compounds, so the heat dissipation of the semiconductor package structure made using the method 2000 is better than conventional semiconductor packages.

In some embodiments, the packaging method 2000 further comprises steps 2060 and 2070.

Step 2060—forming at least one through hole on the passivation layer. The through holes correspond to the third bonding pads one to one, and the through holes expose the corresponding third bonding pads.

Step 2070—forming first electrode structures over respective ones of the third bonding pads and in electrical contact with respective ones of the third bonding pads.

In some embodiments, the at least one first packaged component includes multiple first packaged components, and the at least one first groove includes multiple first grooves equal in depth, and the packaging method 2000 further comprises thinning at least some of the first packaged components so that the multiple first packaged components have equal depth.

In some embodiments, the at least one first packaged component includes at least two first packaged components of unequal thicknesses, and the at least one first groove includes at least two first grooves of unequal depths such that upper surfaces of the first bonding pads of the at least two first packaged components are flush.

In some embodiments, fixing the at least one first packaged component in one-to-one correspondence in the at least one first groove, respectively, comprises forming an insulating adhesive layer at a bottom surface of each first groove, affixing each first packaged component on the insulating adhesive layer in a corresponding first groove, reserving a gap between the first packaged component each side surface of the corresponding first groove, and filling the gap between the first packaged component and each side surface of the corresponding first groove with an insulating material.

In some embodiments, filling the gap between the first packaged component and each side surface of the corresponding first groove with an insulating material comprises injecting and curing a resin material between the first packaged component and the corresponding first groove side surface, or depositing an inorganic oxide insulating material in the gap between the first packaged component and the corresponding first groove side surface.

In some embodiments, fixing the at least one second packaged component in one-to-one correspondence in the at least one second groove, respectively, comprises forming an insulating adhesive layer at a bottom surface of each second groove, affixing each second packaged component on the insulating adhesive layer in a corresponding second groove, reserving a gap between the second packaged component each side surface of the corresponding second groove, and filling the gap between the second packaged component and each side surface of the corresponding second groove with an insulating material.

In some embodiments, filling the gap between the second packaged component and each side surface of the corresponding second groove with an insulating material comprises injecting and curing a resin material between the second packaged component and the corresponding second groove side surface, or depositing an inorganic oxide insulating material in the gap between the second packaged component and the corresponding second groove side surface.

In some embodiments, forming a planar surface exposing the first bonding pads and the second electrode structure comprises removing portions of the insulating material and the substrate material that are higher than the first bonding pads and the second electrode structure using a grinding process and following with surface treatment.

In some embodiments, the substrate has sufficient area to allow a number of first grooves and second grooves to be formed therein. Method 2000 further comprises dicing the substrate to obtain a plurality of semiconductor packaging structures. At least one semiconductor packaging structure comprises at least one first packaged component, at least one second packaged component, a first groove in which the first packaged component is dispose, a second groove in which the second packaged component is disposed, a redistribution layer electrically connected with the first packaged component and the second packaged component, and a passivation layer above the redistribution layer.

In some embodiments, the insulating material in the redistribution layer comprises a polymer or a molding compound.

In some embodiments, referring to FIGS. 7a to 7f and FIG. 5a, the semiconductor packaging method 2000 can be implemented as follows.

In step 2010, referring to FIG. 7a, a plurality of first grooves H1 and at least one second groove H2 are formed in a substrate 1 by an etching process, wherein the depths of a plurality of first grooves H1 are equal but different from the depths of the at least one second groove H2.

In step 2020, referring to FIG. 7b, an insulating adhesive layer 111 is formed at the groove bottoms of the first and second grooves H1 and H2.

Referring to FIG. 7b, first packaged components 22a and 23a are respectively placed in the first grooves H1, at least one second packaged component 21a is placed in the second groove H2, and the first packaged components 22a and 23a and the second packaged component 21a are all adhered to the insulating adhesive 111. In some embodiments, the first bonding pads 211a of the first packaged component 22a and the first bonding pads 231a of the first packaged component 23a face upward, the thicknesses of the first packaged component 22a and the first packaged component 23a are equal, and the upper surfaces of the first bonding pads 221a and 231a and the second electrode structure 211a are flush. The first packaged component 22a, 23a and the second packaged component 21a are spaced from the side walls of the recesses H1, H2.

Referring to FIG. 7c, the insulating material 112 is filled and cured into the first grooves H1 and the second groove H2. For example, a liquid epoxy resin is dropped into the gap between the first grooves H1 and the first packaged or to-be-packaged components 22a, 23a, a liquid epoxy resin is dropped into the gap between the second groove H2 and the second packaged or to-be-packaged component 21a, and the epoxy resin is cured by heating. Alternatively, an inorganic insulating material (e.g., silicon dioxide) is deposited into the gaps between the first grooves H1 and the first packaged components 22a, 23a, and an inorganic insulating material is deposited into the gaps between the second groove H2 and the second packaged component 21a.

In step 2030, referring to FIG. 7d, portions of the insulating material 112 higher than the first bonding pads 221a, 231a and the second electrode structure 211a and portions of the substrate material higher than the first bonding pads 221a, 231a and the second electrode structure 211a are removed by grinding, which is followed with a surface treatment process such as chemical cleaning, polishing, etc. to obtain a flat surface exposing the first bonding pads 221a, 231a and the second electrode structure 211a.

In step 2040, referring to FIG. 7e, a redistribution layer 3 is formed on the flat surface, the second electrodes 31 of the redistribution layer 3 are electrically contacted with the first bonding pads 221a and 231a and the second electrode structures 211a, respectively, and the third electrodes 32 of the redistribution layer 3 are interconnected with the second electrodes 31.

Specifically, for example, in step 2040, a polyimide film is formed, and then a patterning process (for example, coating a photoresist, exposing, developing, etching) is performed, so that via holes exposing the first bonding pads 221a and 231a and the second electrode structure 211a are formed in the polyimide film. Afterwards, a process is performed including depositing a metal film, forming a layer of conductive traces 33 connected to the first bonding pads 221a and 231a and the second electrode structure 211a through a patterning process, and forming a second bonding pads 31 by using a metal material in a lower through hole. Then, a polyimide film is formed again, a via hole exposing the lower line is etched, a metal film is deposited, and third pads 32 connected to the lower traces 33 is formed through a patterning process. The redistribution layer may include one or more layers of traces 33.

In some embodiments, the patterning process may be used to form the pattern of the second pad 31 first, form the polyimide film, form the via hole in the polyimide film to expose the second pad 31, and then form the pattern of the first layer trace 33.

The redistribution layer can also be prepared by those skilled in the art according to conventional technologies.

In step 2050, referring to FIG. 7f, a passivation layer 4 is formed on the redistribution layer 3. The passivation layer 4 may be made of silicon nitride (sin), polyimide (polyimide), or the like. The passivation layer 4 serves to protect the elements therebelow.

In step 2060, referring to FIG. 5a, via holes are etched in the passivation layer 4 to expose the respective third electrodes 32, and, in step 2070, first electrode structures 5 are formed on the third electrodes 32. The first electrode structures 5 include, for example, Under Bump Metal (UBM) on the third electrodes 32 and solder balls on the under bump metal. The first electrode structures 5 may also be in the form of bonding pads.

In some embodiments, referring to FIGS. 8a to 8f and FIG. 5b, the semiconductor packaging method 2000 can be implemented as follows.

In step 2010, referring to FIG. 8a, a plurality of first grooves H1 and at least one second groove H2 are formed in the substrate 1 by controlling a grooving process (e.g., step etching or multiple etching), wherein the depths of grooves are different.

In step 2020, referring to FIG. 8b, an insulating adhesive layer 111 is formed on the groove bottoms of the first grooves H1 and the at least one second groove H2.

Referring to FIG. 8b, the first packaged component 22a and the first packaged component 23a are respectively placed in the first grooves H1, the at least one second packaged component 21a is placed in the at least one second groove H2, and the first packaged components 22a, 23a and the at least one second packaged component 21a are all adhered on the insulating adhesive 111. In some embodiments, the first bonding pads 221a of the first packaged component 22a and the first bonding pads 231a of the first packaged component 23a face upward, the upper surfaces of the first bonding pads 221a, 231a and the second electrode structure 211a are flush, the thicknesses of the first packaged components 22a, 23a and the second packaged component 21a are not equal, and the groove depths of the grooves in which the first packaged components 22a, 23a and the second packaged component 21a are located are not equal.

Referring to FIG. 8c, the insulating material 112 is filled and cured into the first groove H1 and the second groove H2. For example, a liquid epoxy resin is dropped into the gap between the first groove H1 and the first package-to-be-packaged component 22a, 23a, and into the gap between the second groove H2 and the second package-to-be-packaged component 21a, and the epoxy resin is cured by heating.

In step 2030, referring to FIG. 8d, portions of the insulating material higher than the first bonding pads 221a, 231a and the second electrode structure 211a, and portions of the substrate material higher than the first bonding pads 221a, 231a and the second electrode structure 211a, are removed by grinding, and then a surface treatment process such as chemical cleaning, polishing, etc. is performed to obtain a flat surface exposing the first bonding pads 221a, 231a and the second electrode structure 211a.

In step 2040, referring to FIG. 8e, a redistribution layer 3 is formed on the flat surface, the second pads 31 of the redistribution layer 3 are respectively in electrical contact with the first bonding pads 221a and 231a and the second electrode structures 211a, and the third pads 32 of the redistribution layer 3 are interconnected with the second pads 31. The redistribution layer 3 at least includes traces 33, vias connecting the traces 33 and the second pads 31, and vias connecting the traces 33 and the third pads 32.

In step 2050, referring to FIG. 8f, a passivation layer 4 is formed on the redistribution layer 3. The passivation layer 4 may be made of silicon nitride (sin), polyimide (polyimide), or the like. The passivation layer 4 serves to protect the elements therebelow.

Instep 2060, referring to FIG. 5b, vias are etched in the passivation layer 4 to expose the respective third electrodes 32, and, in step 2070, first electrode structures 5 are formed on the third electrodes 32. The first electrode structures 5 include, for example, Under Bump Metal (UBM) over the third electrode 32 and solder balls over the under bump metal. The first electrode structures 5 may also be bonding Pads.

Some embodiments further provide a semiconductor device including the foregoing semiconductor package structure. The semiconductor package structure may be further processed, for example, to be combined with other semiconductor packages into an assembly or module.

Some embodiments further provide an electronic product including the foregoing semiconductor device. The electronic product can be any of various electronic products such as mobile phones, computers, servers, smartwatches, and the like.

Due to the improvement of the stability of the semiconductor packaging structure, the stability of the semiconductor devices and the electronic products is correspondingly improved.

The embodiments in the present application are described in a progressive manner, and the same and similar parts among the embodiments can be referred to each other, and each embodiment focuses on the differences from the other embodiments.

The protective scope of the present application is not limited to the above-described embodiments, and it is apparent that various modifications and variations can be made to the present application by those skilled in the art without departing from the scope and spirit of the present application. It is intended that the present application also include such modifications and variations as come in the scope of the appended claims and their equivalents.

What is claimed is:

1. A semiconductor package structure, comprising: a substrate, at least one first packaged component, at least one second packaged component, a redistribution layer, and a passivation layer, wherein:
at least one first groove and at least one second groove are formed in the substrate;
the at least one first packaged component is fixed in the at least one first groove in one-to-one correspondence;
the at least one second packaged component is fixed in the at least one second groove in one-to-one correspondence;
each first packaged component is separated from a corresponding first groove, in which the first package component is disposed, by insulating materials;
each second packaged component is separated from a corresponding second groove, in which the second package component is disposed, by insulating materials;
the at least one first packaged component is in a bare chip state and has at least one active surface facing away from the substrate and first bonding pads on the at least one active surface;
the at least one second packaged component is in a packaged state and is provided with exposed second electrode structures;
surfaces of the first bonding pads facing away from the substrate and surfaces of the second electrode structures facing away from the substrate are flush;
the redistribution layer is formed on one side of the at least one packaged component facing away from the substrate;
the redistribution layer has a first surface formed with a plurality of second bonding pads and a second surface opposite to the first surface and formed with a plurality of third bonding pads;
a first subset of the second bonding pads are in electrical contact with respective ones of the first bonding pads;
a second subset of the second bonding pads are in electrical contact with respective ones of the second electrode structures;
the redistribution layer further includes routing wires to provide electrical interconnection between the second bonding pads and the third pads and routing wires to provide electrical interconnection between the second bonding pads and the second electrode structures;
the passivation layer is positioned on one side of the redistribution layer facing away from the substrate; and
the substrate includes a semiconductor material or an insulating material having a thermal expansion coefficient that is the same as or similar to that of a base semiconductor material in the at least one first packaged component.

2. The semiconductor package structure of claim 1, wherein the semiconductor material in the substrate is the same as the base semiconductor material in the at least one first packaged component.

3. The semiconductor package structure of claim 1, wherein the base semiconductor material in the at least one packaged component is silicon or gallium arsenide, and the material of the substrate is engineered Pyrex.

4. The semiconductor package structure of claim 1, wherein the at least one first packaged component includes multiple first packaged components equal in thickness, and the at least one first groove includes multiple first grooves equal in depth.

5. The semiconductor package structure of claim 1, wherein the at least one first packaged component includes at least two first packaged components of unequal thicknesses, and wherein the at least one first groove includes at least two first grooves of unequal depths such that upper surfaces of the first bonding pads of the at least two first packaged components are flush.

6. The semiconductor package structure according to claim 1, further comprising first electrode structures on a side of the passivation layer facing away from the substrate, wherein via holes are formed in the passivation layer, the first electrode structures corresponding to the third pads one by one and being electrically connected to the corresponding third pads through the via holes.

7. The semiconductor package structure of claim 1, wherein each first packaged component is separated from the bottom of a corresponding groove by an insulating adhesive layer.

8. The semiconductor package structure of claim 1, wherein each first packaged component is separated from side surfaces of a corresponding first groove by a cured resin material or an inorganic insulating material, and wherein each second packaged component is separated from side surfaces of a corresponding second recess by a cured resin material or an inorganic insulating material.

9. The semiconductor package structure of claim 1, wherein the redistribution layer includes conductive traces separated from each other by a polymer or a molding compound.

10. The semiconductor package structure of claim 1, wherein each second packaged component is a chip-on-chip package or a ceramic package.

11. A semiconductor packaging method, comprising:
forming at least one first groove and at least one second groove in a substrate;
fixing at least one first packaged component in the at least one groove in one-to-one correspondence and at least one second packaged component in the at least one second groove in one-to-one correspondence, wherein the at least one first packaged component is in a bare chip state, the at least one second packaged component is in a packaged state and has exposed second electrode structures, each first packaged component is separated from a corresponding groove in which the packaged component is located by one or more insulating materials, each second packaged component is separated from a corresponding second groove in which the packaged component is located by one or more insulating materials, the at least one first packaged component has at least one active surface facing away from the substrate and first bonding pads on the at least one active surface, and surfaces of the first bonding pads facing away from the substrate and surfaces of the second electrode structures facing away from the substrate are flush;
forming a planar surface exposing the first bonding pads and the second electrode structures;
forming a redistribution layer, the redistribution layer having a first surface formed with a plurality of second bonding pads and a second surface opposite to the first surface and formed with a plurality of third bonding pads, a first subset of the second bonding pads being in electrical contact with respective ones of the first bonding pads, a second subset of the second bonding pads being in electrical contact with respective ones of the second electrode structures, the redistribution layer further including routing wires to provide electrical interconnection between the second bonding pads and the third pads and routing wires to provide electrical interconnection between the second bonding pads and the second electrode structures;
forming a passivation layer;
wherein the substrate includes a semiconductor material or an insulating material, and a thermal expansion coefficient of the substrate is the same as or similar to that of a base semiconductor material in the at least one first packaged component.

12. The semiconductor packaging method of claim 11, wherein the semiconductor material in the substrate is the same as the base semiconductor material in the packaged component.

13. The semiconductor packaging method of claim 11, wherein the base semiconductor material in the packaged component is silicon or gallium arsenide, and the material of the substrate is engineered Pyrex.

14. The semiconductor packaging method of claim 11, wherein the at least one first packaged component includes multiple packaged components equal in thickness, and the at least one first groove includes multiple first grooves equal in depth.

15. The semiconductor packaging method of claim 11, wherein the at least one first packaged component includes at least two first packaged components of unequal thicknesses, and the at least one first groove includes at least two first grooves of unequal depths such that upper surfaces of the first bonding pads of the at least two first packaged components are flush.

16. The semiconductor packaging method of claim 11, wherein fixing the at least one first or second packaged component in one-to-one correspondence in the at least one first or second groove, respectively, comprises:
forming an insulating adhesive layer at a bottom surface of each first or second groove;
affixing each first or second packaged component on the insulating adhesive layer in a corresponding first or second groove, reserving a gap between the first or second packaged component each side surface of the corresponding first or second groove; and
filling the gap between the first or second packaged component and each side surface of the corresponding first or second groove with an insulating material.

17. The semiconductor packaging method of claim 16, wherein filling the gap between the first or second packaged component and each side surface of the corresponding first or second groove with an insulating material comprises:
injecting and curing a resin material between the first or second packaged component and the corresponding first or second groove side surface, or depositing an inorganic oxide insulating material in the gap between the first or second packaged component and the corresponding first or second groove side surface.

18. The method of claim 33, wherein forming a planar surface exposing the first bonding pads and the second electrode structure comprises:
removing portions of the insulating material and the substrate material that are higher than the first bonding pads and the second electrode structure using a grinding process and following with surface treatment.

19. The method of claim 11, further comprising:
forming a plurality of via holes in the passivation layer, wherein the via holes correspond, respectively, to the third bonding pads and exposing the corresponding third bonding pads; and
forming first electrode structures in electrical contact, respectively, with the third pads.

20. A semiconductor packaging method, comprising:
forming at least one groove on a substrate;
fixing at least one packaged component in the at least one groove in one-to-one correspondence, wherein each packaged component is separated from a corresponding groove in which the packaged component is located by one or more insulating materials, the at least one packaged component has at least one active surface facing away from the substrate and first bonding pads on the at least one active surface, and surfaces of the first bonding pads facing away from the substrate are flush;
forming a flat surface exposing the first bonding pads;
forming a redistribution layer, the redistribution layer having a first surface formed with a plurality of second bonding pads and a second surface opposite to the first surface and formed with a plurality of third bonding pads, the second bonding pads being in electrical contact with respective ones of the first bonding pads, the redistribution layer further including routing wires electrically connected with the second bonding pads and the third bonding pads; and
forming a passivation layer;
wherein the substrate includes a semiconductor material or an insulating material, and a thermal expansion coefficient of the substrate is the same as or similar to that of a base semiconductor material in the packaged component.
